(19) United States
(12) Patent Application Publication
(10) Pub. No.: US 2026/0223456 A1
(43) Pub. Date: Jul. 30, 2026

(54) DISPLAY PANEL, METHOD FOR MANUFACTURING SAME, AND DISPLAY DEVICE

(71) Applicant: Guangzhou China Star Optoelectronics Semiconductor Display Technology Co., LTd., Guangzhou (CN)

(72) Inventors: Jun ZHAO, Guangzhou (CN); Juncheng XIAO, Guangzhou (CN); Xiaolin YAN, Guangzhou (CN); Bin ZHAO, Guangzhou (CN); Hui XIAO, Guangzhou (CN); Daobing HU, Guangzhou (CN)

(73) Assignee: Guangzhou China Star Optoelectronics Semiconductor Display Technology Co., LTd., Guangzhou (CN)

(21) Appl. No.: 19/248,299

(22) Filed: Jun. 24, 2025

(30) Foreign Application Priority Data
Jan. 24, 2025 (CN) 202510121244.3

(51) Int. Cl. H10D 86/40; H10D 86/01; H10D 86/60

(52) U.S. Cl. CPC H10D 86/431; H10D 86/0221; H10D 86/423; H10D 86/60

(57) ABSTRACT

A display panel, a method for manufacturing the display panel, and a display device. The display panel includes a substrate, a buffer layer, an active layer, a gate insulating layer, and a gate layer. At least one of the buffer layer and the gate insulating layer has a laminated structure formed by stacking two layers of the same material, and the hydrogen content in the film layer of the laminated structure adjacent to the active layer is lower than that in the film layer of the laminated structure away from the active layer. The active layer is provided as a laminated structure formed by the first active sublayer and the second active sublayer, and the mobility of the first active sublayer is made greater than that of the second active sublayer.

### CROSS-REFERENCE TO RELATED APPLICATION

This application claims priority to and the benefit of Chinese Patent Application No. 202510121244.3, filed on Jan. 24, 2025, the disclosure of which is incorporated herein by reference in its entirety.

### TECHNICAL FIELD

This application relates to the field of display technology, and in particular, to a display panel, a method for manufacturing the display panel, and a display device.

### BACKGROUND

Compared with the currently mainstream display panels with an active layer of amorphous silicon, display panels with an active layer of oxide semiconductor have technical advantages such as high electron mobility, high on-off current ratio, feasibility of flexible display, good uniformity, and low production cost, and have been widely favored by the industry.

The pixel driving circuit in the display area and the gate driving circuit in the non-display area have different requirements for the characteristics of thin-film transistor devices. The display area requires that the thin-film transistors have high uniformity, while the non-display area requires that the thin-film transistors have a large margin. Limited by the current process, the margin of the thin-film transistors in the non-display area is low and cannot meet the requirements.

Therefore, it is necessary to provide a display panel, a method for manufacturing the display panel, and a display device to improve this defect.

### SUMMARY

Embodiments of the present disclosure provide a display panel, a method for manufacturing the display panel, and a display device, which can improve the uniformity of the performance of the thin-film transistors in the display area.

To achieve the above objective, according to a first aspect of the present disclosure, a display panel is provided, including:
a substrate;
a buffer layer disposed on one side of the substrate;
an active layer disposed on a side of the buffer layer away from the substrate, a material of the active layer including an oxide semiconductor material;
a gate insulating layer disposed on a side of the active layer away from the buffer layer;
a gate layer disposed on a side of the gate insulating layer away from the active layer;
where at least one of the buffer layer and the gate insulating layer has a laminated structure formed by stacking two layers of a same material, and a hydrogen content in a film layer of the laminated structure adjacent to the active layer is less than that in a film layer of the laminated structure away from the active layer; the active layer includes a first active sublayer and a second active sublayer, the second active sublayer is disposed on a side of the first active sublayer adjacent to the gate layer, and a mobility of the first active sublayer is greater than that of the second active sublayer.

Optionally, a thickness of the first active sublayer is greater than that of the second active sublayer.

Optionally, a thickness of the first active sublayer is greater than or equal to 200 angstroms and less than or equal to 1000 angstroms, and a thickness of the second active sublayer is greater than or equal to 50 angstroms and less than or equal to 500 angstroms.

Optionally, the buffer layer includes:
a first buffer sublayer disposed on one side of the substrate, a material of the first buffer sublayer including silicon nitride;
a second buffer sublayer disposed on a side of the first buffer sublayer away from the substrate, a material of the second buffer sublayer including silicon oxide;
a third buffer sublayer disposed on a surface of the second buffer sublayer away from the first buffer sublayer, a material of the third buffer sublayer including silicon oxide;
where a hydrogen content in the third buffer sublayer is less than that in the second buffer sublayer.

Optionally, a thickness of the second buffer sublayer is greater than that of the third buffer sublayer.

Optionally, a thickness of the second buffer sublayer is greater than or equal to 2000 angstroms and less than or equal to 4000 angstroms, and a thickness of the third buffer sublayer is greater than or equal to 200 angstroms and less than or equal to 1000 angstroms.

Optionally, the buffer layer further includes a fourth buffer sublayer, the fourth buffer sublayer disposed between the first buffer sublayer and the second buffer sublayer;
where a material of the fourth buffer sublayer includes silicon nitride, and a hydrogen content in the fourth buffer sublayer is less than that in the first buffer sublayer.

Optionally, the thickness of the fourth buffer sublayer is less than that of the first buffer sublayer.

Optionally, the gate insulating layer includes:
a first gate insulating sublayer disposed on a side of the active layer away from the substrate;
a second gate insulating sublayer disposed on a surface of the first gate insulating sublayer away from the active layer;
where a hydrogen content in the first gate insulating sublayer is less than that in the second gate insulating sublayer.

Optionally, a thickness of the first gate insulating sublayer is less than that of the second gate insulating sublayer.

Optionally, a thickness of the first gate insulating sublayer is greater than or equal to 200 angstroms and less than or equal to 600 angstroms, and a thickness of the second gate insulating sublayer is greater than or equal to 1000 angstroms and less than or equal to 2000 angstroms.

Optionally, the display panel further includes:
an interlayer dielectric layer disposed on a side of the gate layer away from the gate insulating layer;
a source-drain layer disposed on a side of the interlayer dielectric layer away from the gate layer;
a first passivation layer disposed on a side of the source-drain layer away from the interlayer dielectric layer;
an organic insulating layer disposed on a side of the first passivation layer away from the source-drain layer;
a second passivation layer disposed on a side of the organic insulating layer away from the first passivation layer;
where the second passivation layer includes a first passivation sublayer and a second passivation sublayer, the second passivation sublayer is disposed on a surface of the first passivation sublayer away from the organic insulating layer, and a hydrogen content in the first passivation sublayer is less than that in the second passivation sublayer.

Optionally, a thickness of the first passivation sublayer is less than that of the second passivation sublayer.

According to a second aspect of the present disclosure, a method for manufacturing a display panel is provided. The method for manufacturing the display panel includes the following steps:
forming a buffer layer on one side of a substrate;
forming a first active sublayer on a side of the buffer layer away from the substrate;
forming a second active sublayer on the first active sublayer to obtain an active layer;
forming a gate insulating layer on a side of the active layer away from the buffer layer;
forming a gate layer on a side of the gate insulating layer away from the active layer;
wherein at least one of the buffer layer and the gate insulating layer has a laminated structure formed by stacking two layers of a same material, a film formation rate of a film layer of the laminated structure adjacent to the active layer is slower than that of a film layer of the laminated structure away from the active layer, a hydrogen content in the film layer of the laminated structure adjacent to the active layer is lower than that in the film layer of the laminated structure away from the active layer, and a mobility of the first active sublayer is greater than that of the second active sublayer.

According to a third aspect of the present disclosure, a display device is provided, including the display panel as described above.

In the display panel of the embodiments of the present disclosure, at least one of the buffer layer and the gate insulating layer has a laminated structure formed by stacking two layers of the same material, and the hydrogen content in the film layer of the laminated structure adjacent to the active layer is lower than that in the film layer of the laminated structure away from the active layer. In this way, the film layer with a lower hydrogen content can be used to block the diffusion of hydrogen during the process to the active layer, thereby improving the uniformity of the performance of the thin-film transistors in the display area. By setting the active layer as a laminated structure formed by stacking the first active sublayer and the second active sublayer, and making the mobility of the first active sublayer greater than that of the second active sublayer, the sub-threshold swing of the thin-film transistor can be increased without affecting the initial threshold voltage of the thin-film transistor, so as to increase the margin of the thin-film transistor.

Other features and advantages of the present disclosure will be described in detail in the subsequent detailed description section.

### BRIEF DESCRIPTION OF THE DRAWINGS

To more clearly illustrate the technical solutions in the embodiments of the present disclosure, the following briefly introduces the drawings required for the description of the embodiments. Obviously, the drawings in the following description are only some embodiments of the present disclosure, and a person having ordinary skill in the art can obtain other drawings according to these drawings without creative efforts.

To more comprehensively understand the present disclosure and its beneficial effects, the following description will be made in conjunction with the drawings, in which the same reference numerals represent the same parts in the following description.

FIG. 1 is a schematic diagram of a structure of a first display panel provided by an embodiment of the present disclosure;

FIG. 2 is a schematic diagram of a structure of a second display panel provided by an embodiment of the present disclosure;

FIG. 3 is a schematic diagram of a structure of a third display panel provided by an embodiment of the present disclosure;

FIG. 4 is a schematic diagram of a structure of a fourth display panel provided by an embodiment of the present disclosure;

FIG. 5 is a schematic diagram of a structure of a fifth display panel provided by an embodiment of the present disclosure;

FIG. 6 is a flowchart of a method for manufacturing a display panel provided by an embodiment of the present disclosure;

FIG. 7 is a schematic diagram of a structure of a display device provided by an embodiment of the present disclosure.

### LISTING OF REFERENCE NUMERALS

10, Substrate; 11, Buffer layer; 111, First buffer sublayer; 112, Second buffer sublayer; 113, Third buffer sublayer; 114, Fourth buffer sublayer; 12, Active layer; 121, First active sublayer; 122, Second active sublayer; 13, Gate insulating layer; 131, First gate insulating sublayer; 132, Second gate insulating sublayer; 14, Gate layer; 15, Light-shielding layer; 16, Interlayer dielectric layer; 17, Source-drain layer; 18, First passivation layer; 19, Organic insulating layer; 20, First electrode layer; 21, Second passivation layer; 211, First passivation sublayer; 212, Second passivation sublayer; 22, Second electrode layer;
100, Display panel; 200, Housing; 1000, Display device.

### Detailed Description

The technical solutions in the embodiments of the present disclosure will be clearly and completely described below in conjunction with the drawings in the embodiments of the present disclosure. Obviously, the described embodiments are only some of the embodiments of the present disclosure, rather than all of them. Based on the embodiments in the present disclosure, all other embodiments obtained by a person having ordinary skill in the art without creative efforts fall within the protection scope of the present disclosure.

An embodiment of the present disclosure provides a display panel. The display panel includes a substrate, a buffer layer, an active layer, a gate insulating layer, and a gate layer. The buffer layer is disposed on one side of the substrate. The active layer is disposed on the side of the buffer layer away from the substrate. The material of the active layer includes an oxide semiconductor material. The gate insulating layer is disposed on the side of the active layer away from the buffer layer. The gate layer is disposed on the side of the gate insulating layer away from the active layer. At least one of the buffer layer and the gate insulating layer has a laminated structure formed by stacking two layers of the same material. The hydrogen content in the film layer of the laminated structure adjacent to the active layer is lower than that in the film layer of the laminated structure away from the active layer. The active layer includes a first active sublayer and a second active sublayer. The second active sublayer is disposed on the side of the first active sublayer away from the substrate. The mobility of the first active sublayer is greater than that of the second active sublayer.

In the display panel of the embodiments of the present disclosure, at least one of the buffer layer and the gate insulating layer has a laminated structure formed by stacking two layers of the same material, and the hydrogen content in the film layer of the laminated structure adjacent to the active layer is lower than that in the film layer of the laminated structure away from the active layer. In this way, the film layer with a lower hydrogen content can be used to block the diffusion of hydrogen during the process to the active layer, thereby improving the uniformity of the thin-film transistors in the display area. By setting the active layer as a laminated structure formed by the first active sublayer and the second active sublayer, and making the mobility of the first active sublayer greater than that of the second active sublayer, the sub-threshold swing of the thin-film transistor can be increased without affecting the initial threshold voltage of the thin-film transistor, so as to increase the margin of the thin-film transistors in the non-display area while improving the uniformity of the thin-film transistors in the display area.

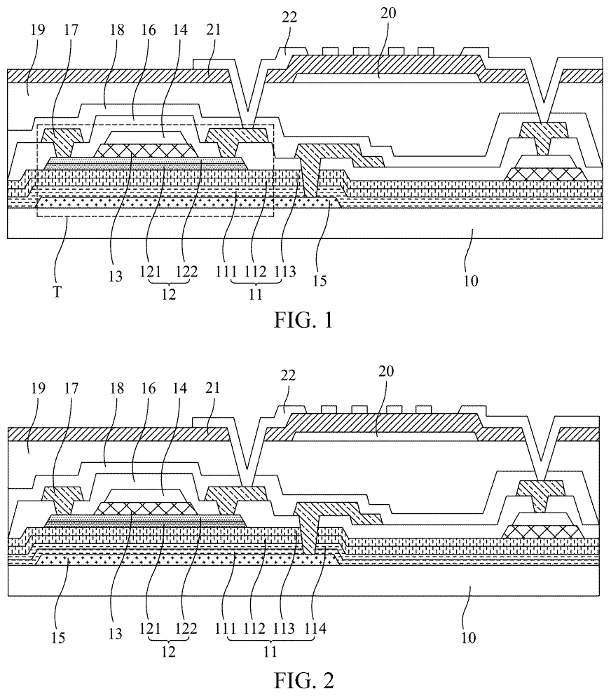

Please refer to FIG. 1. FIG. 1 is a schematic diagram of a structure of a first display panel provided by an embodiment of the present disclosure. The display panel includes a substrate 10, a buffer layer 11, an active layer 12, a gate insulating layer 13, and a gate layer 14. The buffer layer 11 is disposed on one side of the substrate 10, the active layer 12 is disposed on the side of the buffer layer 11 away from the substrate 10, and the material of the active layer 12 includes an oxide semiconductor material. The gate insulating layer 13 is disposed on the side of the active layer 12 away from the buffer layer 11, and the gate layer 14 is disposed on the side of the gate insulating layer 13 away from the active layer 12. At least one of the buffer layer 11 and the gate insulating layer 13 has a laminated structure formed by stacking two layers of the same material. The hydrogen content in the film layer of the laminated structure adjacent to the active layer 12 is lower than that in the film layer of the laminated structure away from the active layer 12. The active layer 12 includes a first active sublayer 121 and a second active sublayer 122. The second active sublayer 122 is disposed on the side of the first active sublayer 121 adjacent to the gate layer 14, and the mobility of the first active sublayer 121 is greater than that of the second active sublayer 122.

In the embodiment of the present disclosure, the display panel includes a display area and a non-display area disposed on a periphery of the display area. The display area is provided with a pixel driving circuit, and the non-display area is provided with a gate driving circuit. Both the pixel driving circuit and the gate driving circuit include thin-film transistors T, and the active layer 12 has a plurality of active portions, and the active portions are involved in forming the thin-film transistors T.

In the embodiment of the present disclosure, at least one of the buffer layer 11 and the gate insulating layer 13 has a laminated structure formed by stacking two layers of the same material, and the hydrogen content in the film layer of the laminated structure adjacent to the active layer 12 is lower than that in the film layer of the laminated structure away from the active layer 12. In this way, the film layer with a lower hydrogen content can be used to block the diffusion of hydrogen during the process to the active layer 12, thereby improving the uniformity of the thin-film transistors in the display area. By setting the active layer 12 as a laminated structure formed by the first active sublayer 121 and the second active sublayer 122, and making the mobility of the first active sublayer 121 greater than that of the second active sublayer 122, the sub-threshold swing of the thin-film transistor T can be increased without affecting the initial threshold voltage of the thin-film transistor T, so as to increase the margin of the thin-film transistors in the non-display area while improving the uniformity of the performance of the thin-film transistors in the display area.

In some embodiments, the mobility of the first active sublayer 121 is greater than or equal to 20 m²/Vs and less than or equal to 50 m²/Vs; the mobility of the second active sublayer 122 is less than or equal to 10 m²/Vs.

In some embodiments, referring to FIG. 1, the substrate 10 is a hard substrate, and the material of the substrate 10 is glass. In other embodiments, the substrate 10 may also be a flexible substrate, and the material of the flexible substrate may be a transparent organic material such as polyimide.

In some embodiments, referring to FIG. 1, the first active sublayer 121 is disposed on the surface of the buffer layer 11 away from the substrate 10, and the second active sublayer 122 is disposed on the surface of the first active sublayer 121 away from the buffer layer 11. The thickness of the first active sublayer 121 is greater than that of the second active sublayer 122, and the first active sublayer 121 is the main part of the active layer 12. In this way, it can be ensured that the active layer 12 has a high mobility. By forming a second active sublayer 122 with a thin thickness and a low mobility on the first active sublayer 121, the sub-threshold swing of the thin-film transistor can be increased without affecting the initial threshold voltage of the transistor, so as to increase the margin of the thin-film transistors in the non-display area while improving the uniformity of the thin-film transistors in the display area.

In some embodiments, the thickness of the first active sublayer 121 is greater than or equal to 200 angstroms and less than or equal to 1000 angstroms, and the thickness of the second active sublayer is greater than or equal to 50 angstroms and less than or equal to 500 angstroms. For example, the thickness of the first active sublayer 121 is 200 angstroms, 400 angstroms, 600 angstroms, 800 angstroms or 1000 angstroms, etc.; the thickness of the second active sublayer 122 is 50 angstroms, 80 angstroms, 100 angstroms, 200 angstroms, 300 angstroms, 400 angstroms or 500 angstroms, etc. It only needs to ensure that the thickness of the first active sublayer 121 is greater than that of the second active sublayer 122, so that the sub-threshold swing of the thin-film transistor can be increased without affecting the initial threshold voltage of the transistor, and thus the margin of the thin-film transistors in the non-display area can be increased while improving the uniformity of the thin-film transistors in the display area.

In some embodiments, the materials of both the first active sublayer 121 and the second active sublayer 122 include an oxide semiconductor material, and the oxide semiconductor material may be, but is not limited to, a metal oxide semiconductor material such as indium gallium zinc oxide.

In some embodiments, the materials of the first active sublayer 121 and the second active sublayer 122 are the same, and the first active sublayer 121 and the second active sublayer 122 can be sequentially prepared and formed in the same process using one photomask.

In some embodiments, referring to FIG. 1, the buffer layer 11 includes a first buffer sublayer 111, a second buffer sublayer 112, and a third buffer sublayer 113. The first buffer sublayer 111 is disposed on one side of the substrate 10, and the material of the first buffer sublayer 111 includes silicon nitride. The second buffer sublayer 112 is disposed on the side of the first buffer sublayer 111 away from the substrate 10, and the material of the second buffer sublayer 112 includes silicon oxide. The third buffer sublayer 113 is disposed on the surface of the second buffer sublayer 112 away from the first buffer sublayer 111, and the material of the third buffer sublayer 113 includes silicon oxide.

It should be noted that by increasing the film formation rate of the second buffer sublayer 112, the film formation time of the buffer layer 11 can be reduced, and the process efficiency can be improved. By reducing the film formation rate of the third buffer sublayer 113, the hydrogen content in the third buffer sublayer 113 can be made less than that in the second buffer sublayer 112, and the third buffer sublayer 113 can have good film formation quality, so that it has good contact with the active layer 12. During the preparation process, the third buffer sublayer 113 with a slow film formation rate and a low hydrogen content can be used to block the diffusion of hydrogen in the second buffer sublayer 112 and the first buffer sublayer 111 to the active layer 12, thereby improving the uniformity of the thin-film transistors.

It should be noted that the hydrogen content in the present disclosure refers to the atomic percentage of hydrogen element in the material of the film layer. Taking the second buffer sublayer 112 and the third buffer sublayer 113 as an example, the fact that the hydrogen content in the third buffer sublayer 113 is less than that in the second buffer sublayer 112 means that the atomic percentage of hydrogen element in the third buffer sublayer 113 is less than that in the second buffer sublayer 112. The atomic percentages of hydrogen element in the second buffer sublayer 112 and the third buffer sublayer 113 can be detected by a detection device such as a mass spectrometer.

In some embodiments, the thickness of the second buffer sublayer 112 is greater than that of the third buffer sublayer 113. It should be noted that because the film formation rate of the second buffer sublayer 112 is fast, by increasing the thickness of the second buffer sublayer 112, the film formation time of the buffer layer 11 can be further reduced, thereby improving the process efficiency.

In some embodiments, the thickness of the second buffer sublayer 112 is greater than or equal to 2000 angstroms and less than or equal to 4000 angstroms, and the thickness of the third buffer sublayer 113 is greater than or equal to 200 angstroms and less than or equal to 1000 angstroms. For example, the thickness of the second buffer sublayer 112 is 2000 angstroms, 2500 angstroms, 3000 angstroms, 3500 angstroms or 4000 angstroms, etc., and the thickness of the third buffer sublayer 113 is 200 angstroms, 400 angstroms, 600 angstroms, 800 angstroms or 1000 angstroms, etc. In this way, it can be ensured that while reducing the film formation time of the buffer layer 11 and improving the process efficiency, the film formation quality of the buffer layer 11 is improved, and the uniformity of the thin-film transistors is improved.

In some embodiments, referring to FIG. 2, FIG. 2 is a schematic diagram of a structure of a second display panel provided by an embodiment of the present disclosure. Its structure is roughly the same as that of the display panel shown in FIG. 1, and the difference is that: the buffer layer 11 further includes a fourth buffer sublayer 114, the fourth buffer sublayer 114 is disposed between the first buffer sublayer 111 and the second buffer sublayer 112, and the hydrogen content in the fourth buffer sublayer 114 is less than that in the first buffer sublayer 111.

In the present embodiment, by adding a fourth buffer sublayer 114 between the first buffer sublayer 111 and the second buffer sublayer 112, the film formation rate of the fourth buffer sublayer 114 is less than that of the first buffer sublayer 111, so that the fourth buffer sublayer 114 has a low hydrogen content. In this way, the fourth buffer sublayer 114 can be used to block the diffusion of hydrogen in the first buffer sublayer 111 to the active layer 12, thereby further improving the uniformity of the thin-film transistors.

In some embodiments, the thickness of the fourth buffer sublayer 114 is less than that of the first buffer sublayer 111. Because the film formation rate of the fourth buffer sublayer 114 is slower than that of the first buffer sublayer 111, by making the thickness of the fourth buffer sublayer 114 less than that of the first buffer sublayer 111, both the process efficiency and the film formation quality of the buffer layer 11 can be taken into account.

In some embodiments, referring to FIG. 1, the gate insulating layer 13 is disposed on the surface of the active layer 12 away from the buffer layer 11, and the gate insulating layer 13 is a single-layer structure formed of a silicon oxide material.

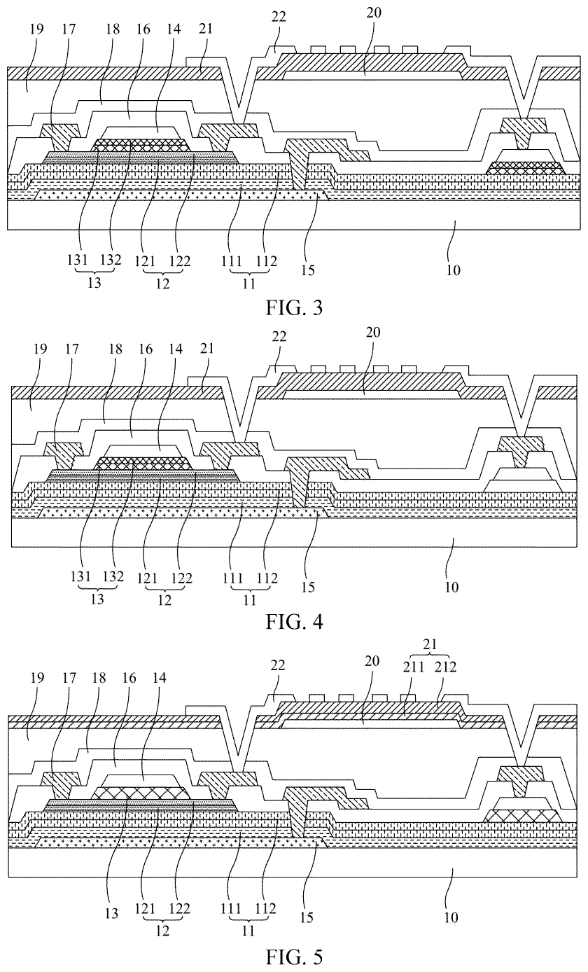

In some embodiments, referring to FIG. 3, FIG. 3 is a schematic diagram of a structure of a third display panel provided by an embodiment of the present disclosure. Its structure is roughly the same as that of the display panel shown in FIG. 1, and the difference is that: the gate insulating layer 13 includes a first gate insulating sublayer 131 and a second gate insulating sublayer 132. The first gate insulating sublayer 131 is disposed on the side of the active layer 12 away from the substrate 10, and the second gate insulating sublayer 132 is disposed on the surface of the first gate insulating sublayer 131 away from the active layer 12. The materials of both the first gate insulating sublayer 131 and the second gate insulating sublayer 132 include silicon oxide, and the hydrogen content in the first gate insulating sublayer 131 is less than that in the second gate insulating sublayer 132. In this way, the first gate insulating sublayer 131 with a low hydrogen content can be used to block the diffusion of hydrogen in the second gate insulating sublayer 132 to the active layer 12, thereby improving the uniformity of the thin-film transistors.

In some embodiments, referring to FIG. 3, the thickness of the first gate insulating sublayer 131 is less than that of the second gate insulating sublayer 132. It should be noted that the film formation rate of the first gate insulating sublayer 131 is less than that of the second gate insulating sublayer 132, so that the hydrogen content in the first gate insulating sublayer 131 can be made less than that in the second gate insulating sublayer 132. By making the thickness of the first gate insulating sublayer 131 less than that of the second gate insulating sublayer 132, the process efficiency of the gate insulating layer 13 can be improved.

In some embodiments, the thickness of the first gate insulating sublayer 131 is greater than or equal to 200 angstroms and less than or equal to 600 angstroms, and the thickness of the second gate insulating sublayer 132 is greater than or equal to 1000 angstroms and less than or equal to 2000 angstroms. For example, the thickness of the first gate insulating sublayer 131 is 200 angstroms, 300 angstroms, 500 angstroms or 600 angstroms, etc., and the thickness of the second gate insulating sublayer 132 is 1000 angstroms, 1300 angstroms, 1500 angstroms, 1700 angstroms or 2000 angstroms.

In some embodiments, referring to FIG. 4, FIG. 4 is a schematic diagram of a structure of a fourth display panel provided by an embodiment of the present disclosure. Its structure is roughly the same as that shown in FIG. 3. In the embodiment shown in FIG. 4, the gate insulating layer 13 includes a first gate insulating sublayer 131 and a second gate insulating sublayer 132, the buffer layer 11 includes a first buffer sublayer 111, a second buffer sublayer 112, and a third buffer sublayer 113, and the buffer layer 11 may also include a fourth buffer sublayer. In this way, it is also possible to achieve the effect of increasing the sub-threshold swing of the thin-film transistor without affecting the initial threshold voltage of the thin-film transistor, so as to increase the margin of the thin-film transistors in the non-display area while improving the uniformity of the thin-film transistors in the display area.

In some embodiments, referring to FIGS. 1 to 4, the display panel further includes a light-shielding layer 15, an interlayer dielectric layer 16, a source-drain layer 17, a first passivation layer 18, an organic insulating layer 19, and a second passivation layer 21. The light-shielding layer 15 is disposed between the substrate 10 and the buffer layer 11, the interlayer dielectric layer 16 is disposed on the side of the gate layer 14 away from the gate insulating layer 13, the source-drain layer 17 is disposed on the side of the interlayer dielectric layer 16 away from the gate layer 14, the first passivation layer 18 is disposed on the side of the source-drain layer 17 away from the interlayer dielectric layer 16, the organic insulating layer 19 is disposed on the side of the first passivation layer 18 away from the source-drain layer 17, and the second passivation layer 21 is disposed on the side of the organic insulating layer 19 away from the first passivation layer 18.

In some implementations, referring to FIGS. 1 to 4, both the interlayer dielectric layer 16 and the first passivation layer 18 are single-layer structures formed of a silicon oxide material, and the second passivation layer 21 is a single-layer structure formed of a silicon nitride material.

In some embodiments, the display panel further includes a first electrode layer 20 and a second electrode layer 22. The first electrode layer 20 is disposed on the surface of the organic insulating layer 19 away from the first passivation layer 18, the second electrode layer 22 is disposed on the side of the second passivation layer 21 away from the organic insulating layer 19, the first electrode layer 20 is one of a common electrode and a pixel electrode, and the second electrode layer 22 is the other of the common electrode and the pixel electrode.

In some embodiments, referring to FIG. 5, FIG. 5 is a schematic diagram of a structure of a fifth display panel provided by an embodiment of the present disclosure. Its structure is roughly the same as that of the display panel shown in FIG. 1, and the difference is that: the second passivation layer 21 includes a first passivation sublayer 211 and a second passivation sublayer 212. The first passivation sublayer 211 is disposed on the surface of the organic insulating layer 19 and the first electrode layer 20 away from the first passivation layer 18, the second passivation sublayer 212 is disposed on the surface of the first passivation sublayer 211 away from the organic insulating layer 19, and the hydrogen content in the first passivation sublayer 211 is less than that in the second passivation sublayer 212.

In the present embodiment, by making the hydrogen content in the first passivation sublayer 211 less than that in the second passivation sublayer 212, the first passivation sublayer 211 with a low hydrogen content can be used to block the diffusion of hydrogen in the second passivation sublayer 212 to the active layer 12, thereby improving the uniformity of the thin-film transistors.

In some embodiments, referring to FIG. 5, the thickness of the first passivation sublayer 211 is less than that of the second passivation sublayer 212. By making the film formation rate of the first passivation sublayer 211 less than that of the second passivation sublayer 212, the hydrogen content in the first passivation sublayer 211 can be made less than that in the second passivation sublayer 212. By making the thickness of the first passivation sublayer 211 less than that of the second passivation sublayer 212, the film formation time of the second passivation layer 21 can be reduced, the process efficiency of the second passivation layer 21 can be improved, and the mass production performance of the second passivation layer 21 can be ensured.

In the embodiment shown in FIG. 5, the buffer layer 11 may be a three-layer laminated structure formed by the first buffer sublayer 111, the second buffer sublayer 112, and the third buffer sublayer 113, or the buffer layer 11 may also be a four-layer laminated structure formed by the first buffer sublayer 111, the fourth buffer sublayer 114, the second buffer sublayer 112, and the third buffer sublayer 113. The gate insulating layer 13 may be a single-layer structure formed of a silicon oxide material, or the gate insulating layer 13 may also be a laminated structure formed by stacking the first gate insulating sublayer 131 and the second gate insulating sublayer 132 as in the above embodiments.

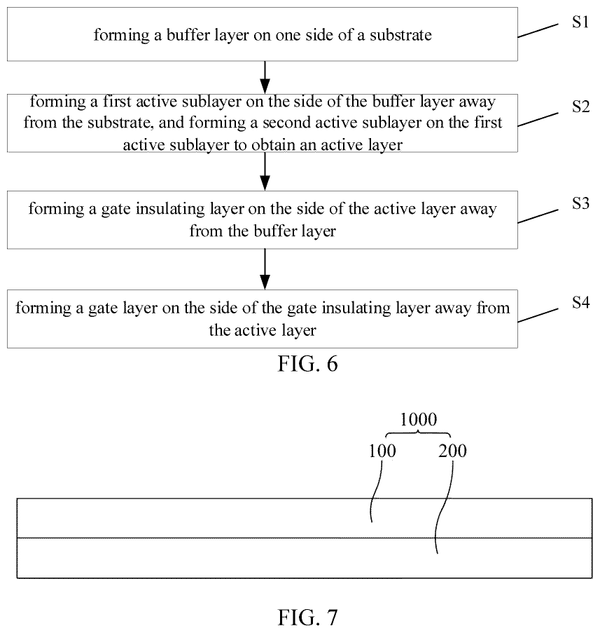

According to the display panel provided in the above embodiments of the present disclosure, the embodiments of the present disclosure also provides a method for manufacturing a display panel. Please refer to FIGS. 1 to 6. FIG. 6 is a flowchart of a method for manufacturing a display panel provided by an embodiment of the present disclosure. The method for manufacturing the display panel includes the following steps:
Step S1, forming a buffer layer 11 on one side of a substrate 10;
Step S2, forming a first active sublayer 121 on the side of the buffer layer 11 away from the substrate 10, and forming a second active sublayer 122 on the first active sublayer 121 to obtain an active layer 12;
Step S3, forming a gate insulating layer 13 on the side of the active layer 12 away from the buffer layer 11;
Step S4, forming a gate layer 14 on the side of the gate insulating layer 13 away from the active layer 12.

In the embodiments of the present disclosure, at least one of the buffer layer 11 and the gate insulating layer 13 has a laminated structure formed by stacking two layers of the same material. The film formation rate of the film layer of the laminated structure adjacent to the active layer 12 is slower than that of the film layer of the laminated structure away from the active layer 12, the hydrogen content in the film layer of the laminated structure adjacent to the active layer 12 is lower than that in the film layer of the laminated structure away from the active layer 12, and the mobility o f the first active sublayer 121 is greater than that of the second active sublayer 122.

In some embodiments, step S1 includes: sequentially depositing a first buffer sublayer 111 on the substrate 10, forming a second buffer sublayer 112 on the first buffer sublayer 111 at a first film formation rate, and forming a third buffer sublayer 113 on the second buffer sublayer 112 at a second film formation rate to obtain the buffer layer 11.

In the present embodiment, the first film formation rate is greater than the second film formation rate. In this way, the hydrogen content in the third buffer sublayer 113 can be made less than that in the second buffer sublayer 112. The third buffer sublayer 113 with a lower hydrogen content can be used to block the diffusion of hydrogen in the second buffer sublayer 112 to the subsequently formed active layer 12, thereby improving the uniformity of the thin-film transistors.

In some embodiments, after the buffer layer 11 is prepared and formed, a baking process can be performed on the buffer layer 11 to release the film stress and improve the film formation quality of the buffer layer 11.

In some embodiments, after the buffer layer 11 is prepared and formed, a nitrous oxide plasma process treatment can be performed on the buffer layer 11 to repair the silicon-oxygen bonds on the surface of the third buffer sublayer 113 in the buffer layer 11, so as to repair the surface defects of the third buffer sublayer 113.

In some embodiments, step S2 further includes: after the active layer 12 is formed, performing a nitrous oxide plasma process treatment on the active layer 12 to repair the defects on the surface of the active layer 12.

In some embodiments, step S3 includes: forming a first gate insulating sublayer 131 on the side of the active layer 12 away from the buffer layer 11 at a third film formation rate, and forming a second gate insulating sublayer 132 on the first gate insulating sublayer 131 at a fourth film formation rate to obtain the gate insulating layer 13.

In the present embodiment, the third film formation rate is less than the fourth film formation rate. In this way, the hydrogen content in the first gate insulating sublayer 131 can be made less than that in the second gate insulating sublayer 132. The first gate insulating sublayer 131 with a lower hydrogen content can be used to block the diffusion of hydrogen in the second gate insulating sublayer 132 to the active layer 12, thereby improving the uniformity of the thin-film transistors.

In some embodiments, the method for manufacturing the display panel further includes the following steps:
Step S5, after the gate layer 14 is formed, performing a dry etching process on the gate insulating layer 13, and simultaneously performing a conductorization treatment on the active layer 12.

In some embodiments, helium and argon are selected as the gases for the conductorization treatment of the active layer 12. In this way, the uniformity of the conductorization of the active layer 12 can be improved, and thus the uniformity of the threshold voltage of the thin-film transistors can be improved.

In some embodiments, the method for manufacturing the display panel further includes the following steps:
Step S6, sequentially forming an interlayer dielectric layer 16, a source-drain layer 17, a first passivation layer 18, an organic insulating layer 19, and a first electrode layer 20 on the gate layer 14;
Step S7, forming a second passivation layer 21 on the organic insulating layer 19 and the first electrode layer 20;
Step S8, forming a second electrode layer 22 on the second passivation layer 21.

In some embodiments, nitrous oxide gas with a high content can be selected during the process of step S6. In this way, the diffusion of hydrogen in the subsequent process to the active layer 12 can be blocked, and thus the uniformity of the performance of the thin-film transistors can be improved.

In some implementations, step S7 includes the following steps: forming a first passivation sublayer 211 on the organic insulating layer 19 and the first electrode layer 20 at a fifth film formation rate; forming a second passivation sublayer 212 on the first passivation sublayer 211 at a sixth film formation rate.

In the present embodiment, because the fifth film formation rate is less than the sixth film formation rate, the hydrogen content in the first passivation sublayer 211 can be made less than that in the second passivation sublayer 212. The first passivation sublayer 211 with a low hydrogen content can be used to block the diffusion of hydrogen in the second passivation sublayer 212 to the active layer 12, thereby improving the uniformity of the thin-film transistors.

According to the display panel provided in the above embodiments of the present disclosure, the embodiments of the present disclosure also provides a display device. Please refer to FIG. 7. FIG. 7 is a schematic diagram of a structure of a display device provided by an embodiment of the present disclosure. The display device 1000 includes a display panel 100 and a housing 200, and the display panel 100 is disposed on the housing 200. The display device 1000 may be the display panel provided in any of the above embodiments. The display device provided in the embodiments of the present disclosure can achieve the same technical effects as the display panel provided in any of the above embodiments, and details are not described herein again.

### Beneficial Effects of the Embodiments of the Present Disclosure

The embodiments of the present disclosure provides a display panel, a method for manufacturing the display panel, and a display device. The display panel includes a substrate, a buffer layer, an active layer, a gate insulating layer, and a gate layer. By making at least one of the buffer layer and the gate insulating layer have a laminated structure formed by stacking two layers of the same material, and the hydrogen content in the film layer of the laminated structure adjacent to the active layer is lower than that in the film layer of the laminated structure away from the active layer, the uniformity of the thin-film transistors in the display area can be improved. By setting the active layer as a laminated structure formed by the first active sublayer and the second active sublayer, and making the mobility of the first active sublayer greater than that of the second active sublayer, the sub-threshold swing of the thin-film transistor can be increased without affecting the initial threshold voltage of the thin-film transistor, so as to increase the margin of the thin-film transistors in the non-display area while improving the uniformity of the thin-film transistors in the display area.

In the description of the present disclosure, the terms “first” and “second” are only used for descriptive purposes, and cannot be construed as indicating or implying relative importance or implicitly indicating the number of indicated technical features. Thus, the features defined with “first” and “second” may explicitly or implicitly include one or more of these features. In the description of the present disclosure, “a plurality of” means two or more, unless specifically defined otherwise.

In the above embodiments, each embodiment is described with emphasis. For parts not described in detail in a certain embodiment, reference may be made to the related descriptions of other embodiments.

The embodiments, implementation manners, and related technical features of the present disclosure may be combined and replaced with each other without conflict.

The above are only the preferred embodiments of the present disclosure, and are not intended to limit the present disclosure in any form. However, any simple amendments, equivalent changes, and modifications made to the above embodiments without departing from the technical solutions of the present disclosure, based on the technical essence of the present disclosure, shall still fall within the scope of the technical solutions of the present disclosure.

What is claimed is:

1. A display panel, comprising:
a substrate;
a buffer layer disposed on one side of the substrate;
an active layer disposed on a side of the buffer layer away from the substrate, a material of the active layer comprising an oxide semiconductor material;
a gate insulating layer disposed on a side of the active layer away from the buffer layer;
a gate layer disposed on a side of the gate insulating layer away from the active layer;
wherein at least one of the buffer layer and the gate insulating layer has a laminated structure formed by stacking two layers of a same material, and a hydrogen content in a film layer of the laminated structure adjacent to the active layer is less than that in a film layer of the laminated structure away from the active layer; the active layer comprises a first active sublayer and a second active sublayer, the second active sublayer is disposed on a side of the first active sublayer adjacent to the gate layer, and a mobility of the first active sublayer is greater than that of the second active sublayer.

2. The display panel of claim 1, wherein a thickness of the first active sublayer is greater than that of the second active sublayer.

3. The display panel of claim 2, wherein a thickness of the first active sublayer is greater than or equal to 200 angstroms and less than or equal to 1000 angstroms, and a thickness of the second active sublayer is greater than or equal to 50 angstroms and less than or equal to 500 angstroms.

4. The display panel of claim 1, wherein the buffer layer comprises:
a first buffer sublayer disposed on one side of the substrate, a material of the first buffer sublayer comprising silicon nitride;
a second buffer sublayer disposed on a side of the first buffer sublayer away from the substrate, a material of the second buffer sublayer comprising silicon oxide;
a third buffer sublayer disposed on a surface of the second buffer sublayer away from the first buffer sublayer, a material of the third buffer sublayer comprising silicon oxide;
wherein a hydrogen content in the third buffer sublayer is less than that in the second buffer sublayer.

5. The display panel of claim 4, wherein a thickness of the second buffer sublayer is greater than that of the third buffer sublayer.

6. The display panel of claim 5, wherein a thickness of the second buffer sublayer is greater than or equal to 2000 angstroms and less than or equal to 4000 angstroms, and a thickness of the third buffer sublayer is greater than or equal to 200 angstroms and less than or equal to 1000 angstroms.

7. The display panel of claim 4, wherein the buffer layer further comprises a fourth buffer sublayer, the fourth buffer sublayer disposed between the first buffer sublayer and the second buffer sublayer;
wherein a material of the fourth buffer sublayer comprising silicon nitride, and a hydrogen content in the fourth buffer sublayer is less than that in the first buffer sublayer.

8. The display panel of claim 7, wherein the thickness of the fourth buffer sublayer is less than that of the first buffer sublayer.

9. The display panel of claim 1, wherein the gate insulating layer comprises:
a first gate insulating sublayer disposed on a side of the active layer away from the substrate;
a second gate insulating sublayer disposed on a surface of the first gate insulating sublayer away from the active layer;
wherein a hydrogen content in the first gate insulating sublayer is less than that in the second gate insulating sublayer.

10. The display panel of claim 9, wherein a thickness of the first gate insulating sublayer is less than that of the second gate insulating sublayer.

11. The display panel of claim 10, wherein a thickness of the first gate insulating sublayer is greater than or equal to 200 angstroms and less than or equal to 600 angstroms, and a thickness of the second gate insulating sublayer is greater than or equal to 1000 angstroms and less than or equal to 2000 angstroms.

12. The display panel of claim 1, wherein the display panel further comprises:
an interlayer dielectric layer disposed on a side of the gate layer away from the gate insulating layer;
a source-drain layer disposed on a side of the interlayer dielectric layer away from the gate layer;
a first passivation layer disposed on a side of the source-drain layer away from the interlayer dielectric layer;
an organic insulating layer disposed on a side of the first passivation layer away from the source-drain layer;
a second passivation layer disposed on a side of the organic insulating layer away from the first passivation layer;
wherein the second passivation layer comprises a first passivation sublayer and a second passivation sublayer, the second passivation sublayer is disposed on a surface of the first passivation sublayer away from the organic insulating layer, and a hydrogen content in the first passivation sublayer is less than that in the second passivation sublayer.

13. The display panel of claim 12, wherein a thickness of the first passivation sublayer is less than that of the second passivation sublayer.

14. A method for manufacturing a display panel, comprising:
forming a buffer layer on one side of a substrate;
forming a first active sublayer on a side of the buffer layer away from the substrate;
forming a second active sublayer on the first active sublayer to obtain an active layer;
forming a gate insulating layer on a side of the active layer away from the buffer layer;
forming a gate layer on a side of the gate insulating layer away from the active layer;
wherein at least one of the buffer layer and the gate insulating layer has a laminated structure formed by stacking two layers of a same material, a film formation rate of a film layer of the laminated structure adjacent to the active layer is slower than that of a film layer of the laminated structure away from the active layer, a hydrogen content in the film layer of the laminated structure adjacent to the active layer is lower than that in the film layer of the laminated structure away from the active layer, and a mobility of the first active sublayer is greater than that of the second active sublayer.

15. A display device, comprising a display panel, the display panel comprising:
a substrate;
a buffer layer disposed on one side of the substrate;
an active layer disposed on a side of the buffer layer away from the substrate, a material of the active layer comprising an oxide semiconductor material;
a gate insulating layer disposed on a side of the active layer away from the buffer layer;
a gate layer disposed on a side of the gate insulating layer away from the active layer;
wherein at least one of the buffer layer and the gate insulating layer has a laminated structure formed by stacking two layers of a same material, and a hydrogen content in a film layer of the laminated structure adjacent to the active layer is less than that in a film layer of the laminated structure away from the active layer; the active layer comprises a first active sublayer and a second active sublayer, the second active sublayer is disposed on a side of the first active sublayer adjacent to the gate layer, and a mobility of the first active sublayer is greater than that of the second active sublayer.

16. The display device of claim 15, wherein a thickness of the first active sublayer is greater than that of the second active sublayer.

17. The display device of claim 16, wherein a thickness of the first active sublayer is greater than or equal to 200 angstroms and less than or equal to 1000 angstroms, and a thickness of the second active sublayer is greater than or equal to 50 angstroms and less than or equal to 500 angstroms.

18. The display device of claim 15, wherein the buffer layer comprises:
a first buffer sublayer disposed on one side of the substrate, a material of the first buffer sublayer comprising silicon nitride;
a second buffer sublayer disposed on a side of the first buffer sublayer away from the substrate, a material of the second buffer sublayer comprising silicon oxide;
a third buffer sublayer disposed on a surface of the second buffer sublayer away from the first buffer sublayer, a material of the third buffer sublayer comprising silicon oxide;
wherein a hydrogen content in the third buffer sublayer is less than that in the second buffer sublayer.

19. The display device of claim 18, wherein a thickness of the second buffer sublayer is greater than that of the third buffer sublayer.

20. The display device of claim 19, wherein a thickness of the second buffer sublayer is greater than or equal to 2000 angstroms and less than or equal to 4000 angstroms, and a thickness of the third buffer sublayer is greater than or equal to 200 angstroms and less than or equal to 1000 angstroms.
